(19) United States
(12) Patent Application Publication
(10) Pub. No.: US 2026/0293305 A1
(43) Pub. Date: Sep. 24, 2026

(54) STACKED TRANSISTORS HAVING OPTIMIZED STRESS AND CAPACITANCE

(71) Applicant: INTERNATIONAL BUSINESS MACHINES CORPORATION, Armonk, NY (US)

(72) Inventors: Eunsoo Cho, Albany, NY (US); Ruilong Xie, Niskayuna, NY (US); Wai Kin Li, Albany, NY (US); Shay Reboh, Guilderland, NY (US); Tenko Yamashita, Schenectady, NY (US); Debarghya Sarkar, Latham, NY (US); Thanh Nguyen, Troy, NY (US)

(21) Appl. No.: 19/086,536

(22) Filed: Mar. 21, 2025

(51) Int. Cl. H10D 84/85; H10D 64/23; H10D 84/01; H10D 84/83

(52) U.S. Cl. CPC H10D 84/856; H10D 64/258; H10D 84/8312; H10D 84/851; H10D 84/017; H10D 84/0186

(57) ABSTRACT

A stacked transistor structure including a bottom transistor comprising a bottom source drain region, where the bottom source drain region directly contacts a gate structure, and a top transistor including a top source drain region, where the top source drain region is physically separated from the gate structure.

### BACKGROUND

The present invention generally relates to semiconductor structures, and more particularly to stacked transistor structures having optimized stress and capacitance.

Integrated circuit (IC) chips are formed on semiconductor wafers at increasingly smaller scale. In current technology nodes, such as 7, 10 and 14 nanometer technologies, transistor devices are constructed as three-dimensional (3D) fin field effect transistor (FINFET) structures. However, chipmakers face a myriad of challenges at 5 nm, 3 nm and beyond. Currently, traditional chip scaling continues to slow as process complexities and costs escalate at each node.

A potential solution to this chip scaling problem is gate-all-around technology. One example of a complex gate-all-around technology is a stacked-FET where nFET and pFET nanowires/nanosheets are vertically stacked on top of each other.

### SUMMARY

According to an embodiment of the present invention, a semiconductor structure is provided. The semiconductor structure may include a bottom transistor including a bottom source drain region, where the bottom source drain region directly contacts a gate structure, and a top transistor including a top source drain region, where the top source drain region is physically separated from the gate structure.

According to another embodiment of the present invention, a semiconductor structure is provided. The semiconductor structure may include a bottom transistor including a bottom source drain region, where the bottom source drain region directly contacts a gate structure, and a top transistor including a top source drain region and inner spacers, where the inner spacers physically separate the top source drain region from the gate structure.

According to another embodiment of the present invention, a semiconductor structure is provided. The semiconductor structure may include a bottom transistor including a bottom source drain region, where the bottom source drain region directly contacts a gate structure, and a top transistor including a top source drain region, where the top source drain region is physically separated from the gate structure, where a width of the gate structure measured at the top transistor is less than a width of the gate structure measured at the bottom transistor.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIG. 2 is a cross-sectional view of a stacked transistor structure during an intermediate step of a method of fabricating a stacked transistor structure according to an exemplary embodiment;

FIG. 3 is a cross-sectional view of the stacked transistor structure after forming a sacrificial material according to an exemplary embodiment;

FIG. 4 is a cross-sectional view of the stacked transistor structure after laterally recessing the sacrificial nanosheets according to an exemplary embodiment;

FIG. 5 is a cross-sectional view of the stacked transistor structure after forming inner spacer liners according to an exemplary embodiment;

FIG. 6 is a cross-sectional view of the stacked transistor structure after removing the sacrificial material and forming bottom source drain regions according to an exemplary embodiment;

FIG. 7 is a cross-sectional view of the stacked transistor structure after depositing a dielectric material, recessing the inner spacer liners and the dialectic material to form inner spacers and middle isolation, respectively, according to an exemplary embodiment;

FIG. 8 is a cross-sectional view of the stacked transistor structure after forming top source drain regions according to an exemplary embodiment;

FIG. 9 is a cross-sectional view of the stacked transistor structure after forming a dielectric layer removing the sacrificial gates, removing the sacrificial nanosheets, forming gate structures, forming top source drain contacts, forming bottom source drain contacts, forming back-end-of-line, and securing a carrier wafer according to an exemplary embodiment;

FIG. 10 is a cross-sectional view of the stacked transistor structure after flipping the assembly and recessing the substrate according to an exemplary embodiment;

FIG. 11 is a cross-sectional view of the stacked transistor structure after forming a backside dielectric layer and backside contacts according to an exemplary embodiment;

FIG. 12 is a cross-sectional view of a stacked transistor structure during an intermediate step of a method of fabricating a stacked transistor structure according to another exemplary embodiment;

FIG. 13 is a cross-sectional view of a stacked transistor structure during an intermediate step of a method of fabricating a stacked transistor structure according to another exemplary embodiment; and

FIG. 14 is a cross-sectional view of a stacked transistor structure during an intermediate step of a method of fabricating a stacked transistor structure according to another exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, or stacked transistors, have known advantages over conventional transistor structures in terms of density, performance, power consumption, and integration. However, fabricating stacked transistor structures having optimized stress and capacitance presents unique challenges. More specifically, for example, current fabrication techniques do not allow for optimized stress and capacitance in PFET devices in a stacked architecture.

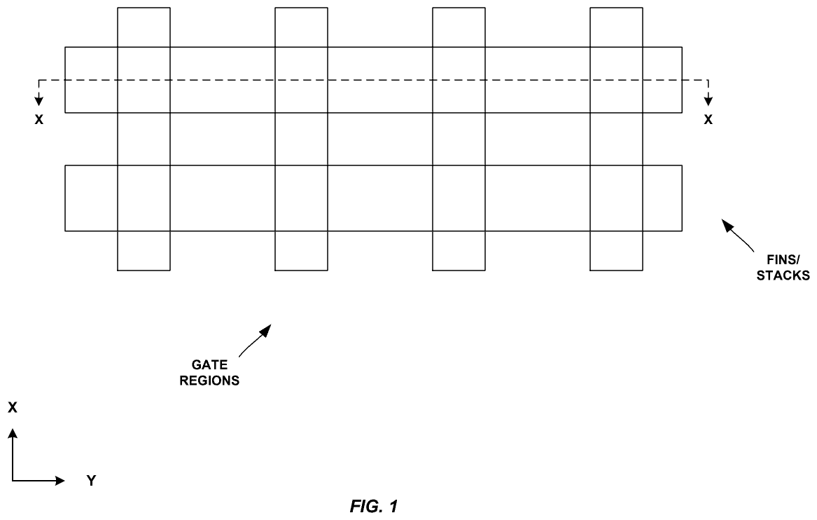

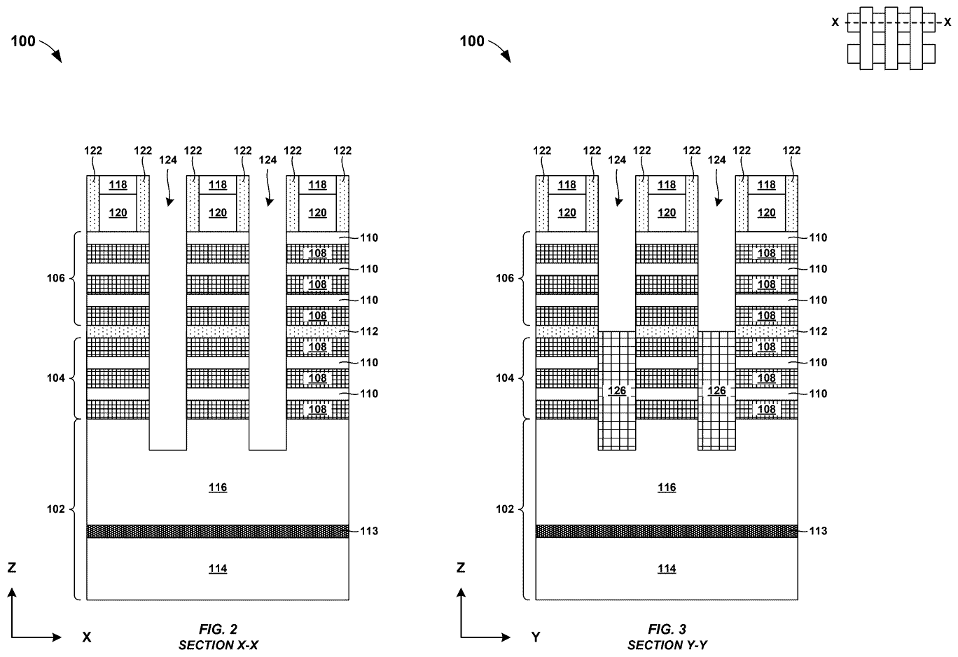

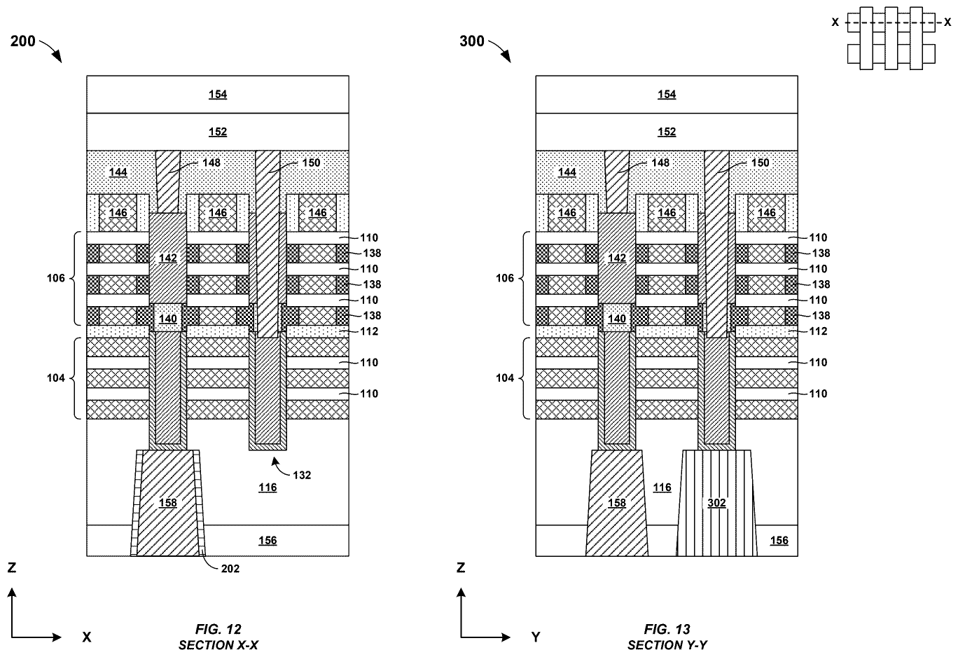

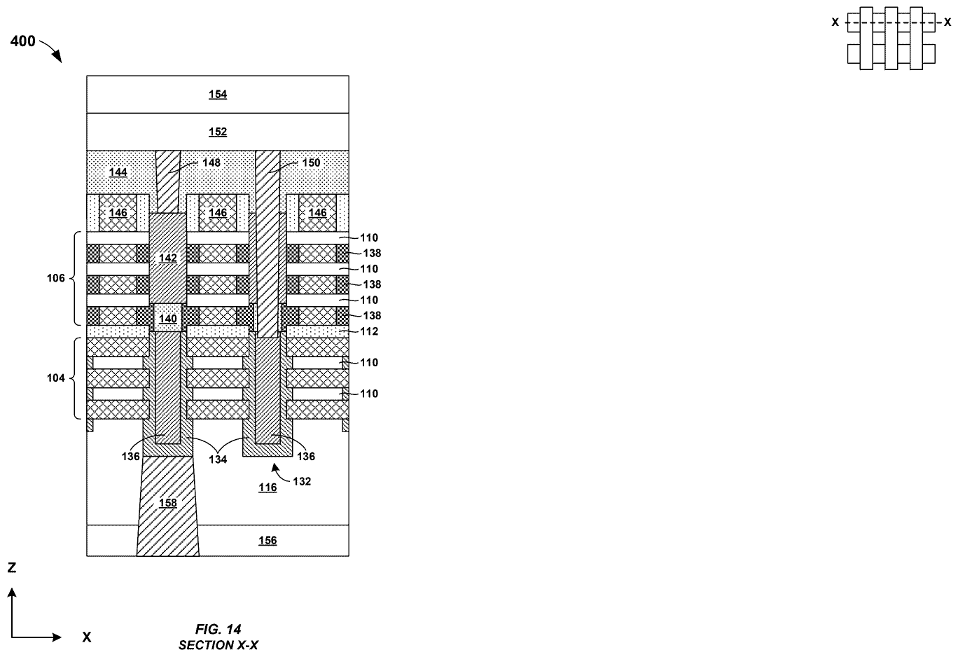

The present invention generally relates to semiconductor structures, and more particularly to stacked transistor structures having optimized stress and capacitance. More specifically, the stacked transistor structures and associated method disclosed herein enable a novel solution for providing stacked transistors where the top transistor and the bottom transistor each have different source drain materials and configurations. Exemplary embodiments of stacked transistor structures having optimized stress and capacitance are described in detail below by referring to the accompanying drawings in FIGS. 1 to 14. Specifically, FIG. 1 illustrates a top view of a generic structure to provide spatial context; FIG. 2-11 illustrate an embodiment; FIG. 12 illustrates a different embodiment; FIG. 13 illustrates a different embodiment; and FIG. 14 and illustrate a different embodiment. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows multiple fins/stacks and multiple gate regions situated perpendicular to one another. FIG. 2-14 represent cross section views oriented as indicated in FIG. 1

Referring now to FIG. 2, a structure 100 is shown during an intermediate step of a method of fabricating a stacked transistor structure according to an embodiment of the invention. FIG. 2 depicts a cross-sectional view taken along line X-X.

The structure 100 illustrated in FIG. 2 includes an array of nanosheet stacks formed on a substrate 102. As illustrated, the structure 100 includes bottom nanosheet stacks 104 and top nanosheet stacks 106 each including an alternating series of silicon germanium (SiGe) sacrificial nanosheets 108 (hereinafter “sacrificial nanosheets 108”) and silicon (Si) channel nanosheets 110 (hereinafter “channel nanosheets 110”), as illustrated. The bottom nanosheet stacks 104 are separated from the top nanosheet stacks 106 by stack isolation layers 112 which are typically made from silicon germanium having a higher concentration of germanium than that of the sacrificial nanosheets 108. For example, the sacrificial nanosheets 108 may have a germanium concentration of about 40% and the stack isolation layers 112 may have a germanium concentration of about 60%. The varying concentrations of germanium enable desired etch selectively between various layers of the top nanosheet stacks 104 and the bottom nanosheet stacks 106 and the stack isolation layers 112.

For purposes of orientation, the substrate 102 is herein referred to as being on a “backside” of the structure 100 and the array of nanosheet stacks are herein referred to as being on a “frontside” of the structure 100. Further, certain features may be described herein as having a relative position with respect to the frontside or backside of the structure 100. Additionally, although only a discrete number of nanosheets are shown, one or more additional sacrificial nanosheets and/or channel nanosheets can optionally be epitaxially grown in an alternating fashion, and the properties of any additional nanosheets are the same as the corresponding nanosheets described herein.

In one or more embodiments, the sacrificial nanosheets 108 the channel nanosheets 110 are formed by epitaxially growing one layer and then the next until a desired number and a desired thickness of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

The substrate 102 may be a layered semiconductor such as a silicon-on-insulator or SiGe-on-insulator, where an etch stop layer 113 separates a base substrate 114 from a top semiconductor layer 116. Unlike conventional layered semiconductor substrates, the etch stop layer 113 of the substrate 102 ay include any material which affects the desired etch selectivity during subsequent processing. For example, the etch stop layer 113 may be a conventional buried oxide layer, or it may be a silicon germanium layer with a specific germanium concentration. In practice, the etch stop layer 113 will function as an etch stop layer and can be composed of any material which supports that function. For example, according to an embodiment, the etch stop layer 113 is made from silicon germanium having a different germanium concentration than other layers in the structure 100.

In the present embodiment, both the base substrate 114 and the top semiconductor layer 116 may be any bulk substrate made from any of several known semiconductor materials such as, for example, silicon, germanium, silicon-germanium alloy, and compound (e.g. III-V and II-VI) semiconductor materials. For example, both the base substrate 114 and the top semiconductor layer 116 may be made from silicon. Additionally, at least both the etch stop layer 113 and the base substrate 114 are sacrificial and will not remain in the final structure.

The structure 100 further includes masks 118, sacrificial gates 120, and gate spacers 122, as illustrated.

The masks 118 are formed on top of a sacrificial gate material blanket deposited across the epitaxial nanosheet layers prior to forming the array of nanosheet stacks. Next a pattern created by the masks 118 is transferred into the sacrificial gate material to form the sacrificial gates 120 according to known techniques and as illustrated. The sacrificial gates 120 are commonly known by persons having skill in the art as dummy gates, and typically made from amorphous silicon (a-Si) or other selectively removable material.

After patterning the sacrificial gates 120, the gate spacers 122 are formed along sidewalls of the sacrificial gates 120 according to known techniques and as illustrated. The gate spacers 122 define the channel length and the source drain regions. In at least one embodiment, the gate spacers 122 include silicon nitride, silicon boron nitride, silicon carbon nitride, silicon boron carbon nitride, or other known equivalents.

Finally, a pattern created by both the masks 118 and the gate spacers 122 is transferred into the epitaxial layers to form the nanosheet stacks according to known techniques and as illustrated. The spaces or trenches created during forming of the nanosheet stacks, are herein referred to as source drain openings 124.

Referring now to FIG. 3, the structure 100 is shown after forming a sacrificial material 126 according to an embodiment of the invention. FIG. 3 depicts a cross-sectional view taken along line X-X.

First, the sacrificial material 126 is deposited according to known techniques. The sacrificial material 126 can be an organic planarization layer (OPL) or a layer of material that is capable of being planarized or etched by known techniques. In an embodiment, for example, the sacrificial material 126 can be an amorphous carbon layer able to withstand subsequent processing temperatures. The sacrificial material 126 can preferably have a thickness sufficient to fill the source drain openings 124 and cover existing structures.

After depositing the sacrificial material 126, a dry etching technique is applied to recess the sacrificial material 126 according to known techniques. Specifically, the sacrificial material 126 is recessed to a level at or below the top nanosheet stacks 106. According to the disclosed embodiments, a topmost surface of the sacrificial material 126 should be at a level between the top and bottom surfaces of the stack isolation layer 112. In all cases the sacrificial material 126 should completely cover, and otherwise protect, sidewalls of the bottom nanosheet stacks 104.

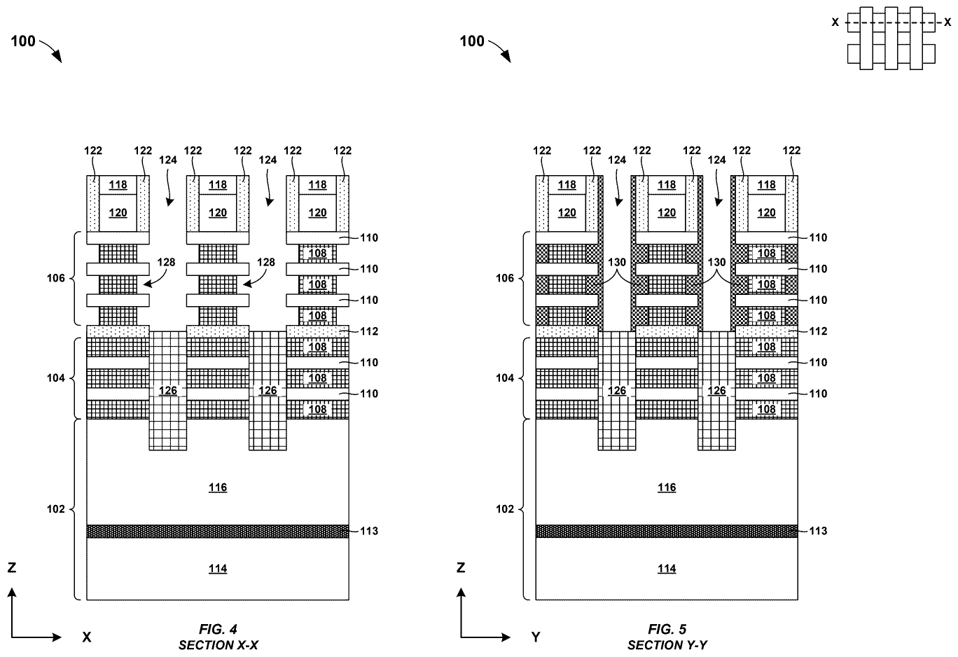

Referring now to FIG. 4, the structure 100 is shown after laterally recessing the sacrificial nanosheets 108 according to an embodiment of the invention. FIG. 4 depicts a cross-sectional view taken along line X-X.

The sacrificial nanosheets 108 of the top nanosheet stacks 106 are laterally recessed according to known techniques. Specifically, according to an embodiment, the sacrificial nanosheets 108 of the top nanosheet stacks 106 are laterally recessed using a hydrogen chloride (HCl) gas isotropic etch process designed to etch silicon germanium without attacking the channel nanosheets 110. In other embodiments, the sacrificial nanosheets 108 are laterally recessed using a ClF3 etch process.

Laterally recessing the sacrificial nanosheets 108 of the top nanosheet stacks 106 forms cavities 128 in the sidewalls of the source drain openings 124. It is noted, the cavities 128 are only formed in the top nanosheet stacks 106, and no cavities are formed in the bottom nanosheet stacks 104. Unique to the disclosed embodiments, the sacrificial material 126 protects the bottom nanosheet stacks 104. More specifically, the sacrificial material 126 protects the sacrificial nanosheets 108 of the bottom nanosheet stacks 104 from being recessed while the cavities 128 are formed in the top nanosheet stacks 106.

Referring now to FIG. 5, the structure 100 is shown after forming inner spacer liners 130 according to an embodiment of the invention. FIG. 5 depicts a cross-sectional view taken along line X-X.

The inner spacer liners 130 are formed within the source drain openings 124 according to known techniques. First a conformal spacer material is conformally deposited over the structure 100 to fill the cavities 128 and substantially fill the source drain openings 124. The conformal spacer material is then isotropically etched to remove all portions except those portions remaining in the cavities 128 and relatively thin portions along sidewalls of the source drain openings 124, as illustrated. Unique to the disclosed embodiments, etching of the inner spacer material is carefully controlled to ensure all surfaces of the channel nanosheets 110 remain covered and protected by remaining inner spacer liners 130, as illustrated. In doing so, the inner spacer liners 130 will completely fill the cavities 128 as well as remain along sidewalls of the source drain openings 124, also as illustrated. Due to the isotropic nature of the selected etching technique, topmost surfaces of the sacrificial material 126 will become exposed.

In one or more embodiments, both the inner spacer liners 130 are made from a nitride containing material, for example silicon nitride (SiN). Alternatively, the inner spacer liners 130 are made from any material which offers selectivity for subsequent device fabrication operations. Selectivity, as used in the present description, refers to the tendency of a process operation to impact a particular material. One example of low selectivity is a relatively slow etch rate. One example of a higher or greater selectivity is a relatively faster etch rate. For the described embodiments, a material for the inner spacer liners 130 can be selected, in part, based on a selectivity of subsequent device fabrication operations for the selected material being below a predetermined threshold.

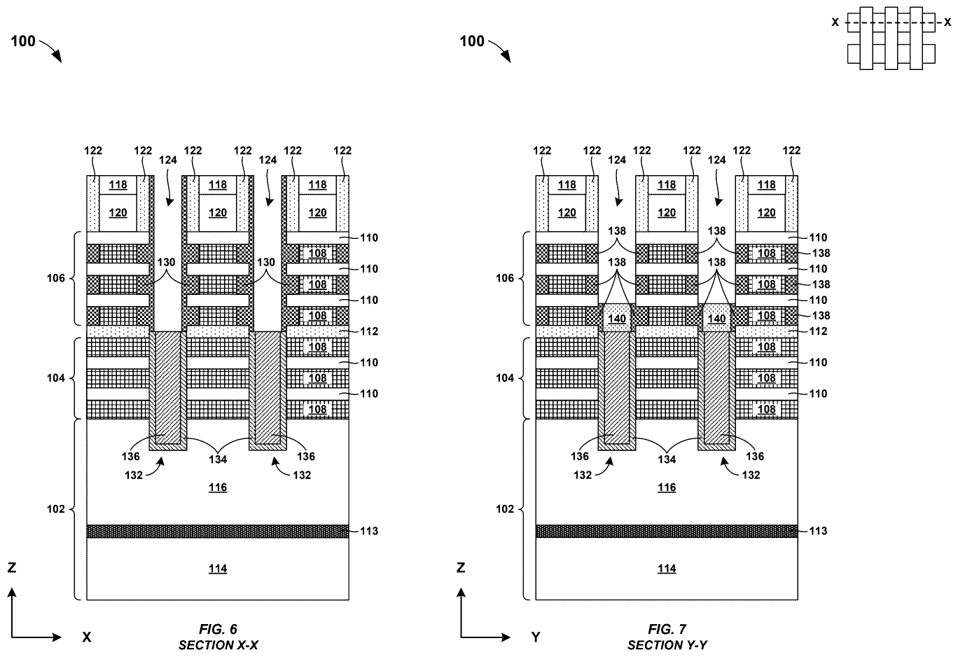

Referring now to FIG. 6, the structure 100 is shown after removing the sacrificial material 126 and forming bottom source drain regions 132 according to an embodiment of the invention. FIG. 6 depicts a cross-sectional view taken along line X-X.

First, the sacrificial material 126 is removed according to known techniques. In an embodiment, the sacrificial material 126 is removed using known techniques, such as, for example, ashing.

Next, the bottom source drain regions 132 are formed according to known techniques. Specifically, an epitaxial layer growth process is used to grow an epitaxy material on the exposed surfaces of both the top semiconductor layer 116 and the channel nanosheets 110 of the bottom nanosheet stacks 104. Unique to the disclosed embodiments, the inner spacer liners 130 prevent the epitaxy material from growing, or otherwise forming, on or adjacent to the top nanosheet stacks 106. As such, the bottom source drain regions 132 are formed adjacent to only the bottom nanosheet stacks 104. Additionally, because the sacrificial nanosheets 108 of the bottom nanosheet stacks 104 were not laterally recessed previously, the bottom source drain regions 132 directly contact the sacrificial nanosheets 108 of the bottom nanosheet stacks 104.

Typically, in-situ doping is used to dope the bottom source drain regions 132, thereby creating the necessary junctions of the semiconductor device. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a P-type piece of silicon, rich in holes, and an N-type piece of silicon, rich in electrons. N-type and P-type devices are formed by using different types of dopants to select regions of the device to form the necessary junction(s). For example, N-type devices can be formed by doping with arsenic (As) or phosphorous (P), and P-type devices can be formed by doping with implanting boron (B).

According to embodiments of the present invention, the bottom source drain regions 132 associated with the bottom nanosheet stacks 104 are multilayered and of a first-type, for example, P-type. According to an embodiment, the bottom source drain regions 132 include a first material 134 and a second material 136 which is different from the first material 134. For example, according to an embodiment, the first material is silicon doped with boron and the second material 136 is silicon germanium doped with boron. Said differently, according to an embodiment, the bottom source drain regions 132 includes a boron doped silicon germanium (SiG:B) core and a boron doped silicon (Si:B) outer shell. In such cases, the boron doped silicon outer shell physically separates the boron doped silicon germanium core from subsequently formed gate structures (for example, see FIG. 9). In all cases, topmost surfaces of the bottom source drain regions 132 should be formed to a height or level at or below a topmost surface of the stack isolation layer 112.

Referring now to FIG. 7, the structure 100 is shown after depositing a dielectric material, recessing the inner spacer liners 130 and the dielectric material to form inner spacers 138 and middle isolation 140, respectively, according to an embodiment of the invention. FIG. 7 depicts a cross-sectional view taken along line X-X.

First, a dielectric material is blanket deposited according to known techniques. Specifically, the dielectric material is deposited such that it fills, or substantially fills, the source drain openings 124. After depositing the dielectric material, known polishing techniques may be applied until a topmost surface of the dielectric material is flush, or substantially flush, with topmost surfaces of the structure 100, for example top surfaces of the masks 118. The dielectric material may include any known interlayer dielectric materials, such as for sample, silicon oxides or silicon nitrides.

Next, both the inner spacer liners 130 and the dielectric material are recessed according to known techniques. Specifically, according to an embodiment, the inner spacer liners 130 and the dielectric material are recessed using an isotropic etching technique designed to etch dielectric, for example silicon nitrides or other nitride containing dielectrics, without attacking the channel nanosheets 110. Etching is designed to remove all portions of the inner spacer liners 130 and the dielectric material except portions remaining in the cavities along sidewalls of the source drain openings 124 and portions remaining at the bottom of the source drain openings 124, as illustrated. Specifically, portions of the inner spacer liners 130 remaining in the cavities along sidewalls of the source drain openings 124 are referred to as the inner spacers 138, and portions of the dielectric layer remaining at the bottom of the source drain openings 124 are referred to as the middle isolation 140.

Etching continues until at least sidewalls of the channel nanosheets 110 of the top nanosheet stacks 106 become exposed. As such, according to an embodiment, the bottommost inner spacers 138 cover some sidewall portions of the bottommost channel nanosheet 110 of the top nanosheet stacks 106, as illustrated. In another embodiment, etching continues until sidewalls of the bottommost channel nanosheet 110 of the top nanosheet stacks 106 are completely exposed. It is noted, the bottommost inner spacers 138 will continue to have portions which protrude laterally beyond sidewalls of the channel nanosheets 110, as illustrated. For example, the bottommost inner spacers 138 will wrap around and directly contact a top and a sidewall of the stack isolation layers 112, as illustrated.

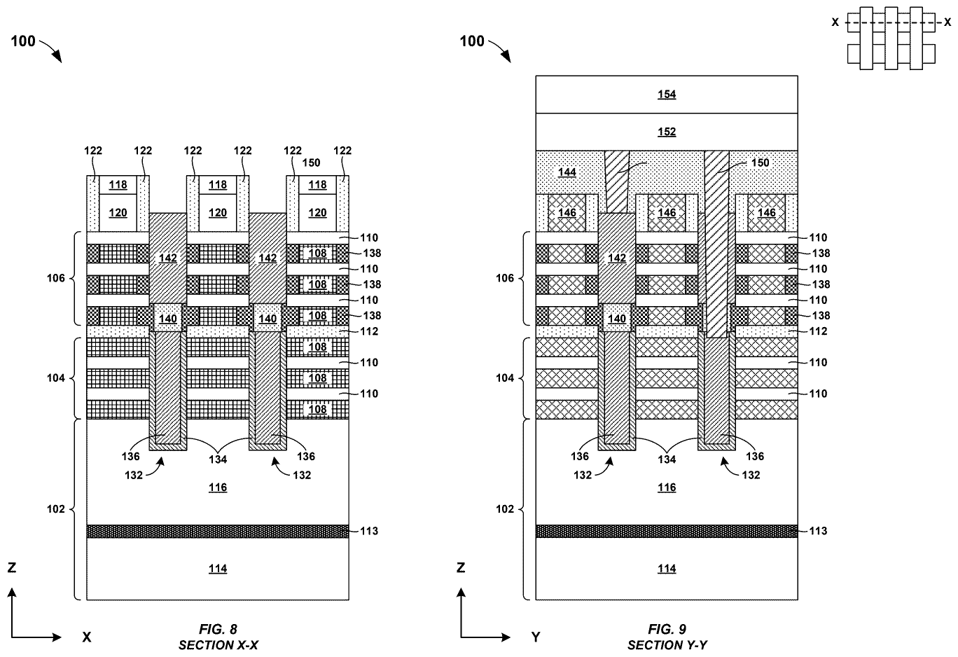

Referring now to FIG. 8, the structure 100 is shown after forming top source drain regions 142 according to an embodiment of the invention. FIG. 8 depicts a cross-sectional view taken along line X-X.

The top source drain regions 142 are formed according to known techniques. Specifically, an epitaxial layer growth process is used to grow an epitaxy material on the exposed surfaces of the channel nanosheets 110 of the top nanosheet stacks 106. Typically, in-situ doping is used to dope the top source drain regions 142, thereby creating the necessary junctions of the semiconductor device, as described above. Unlike the bottom nanosheet stacks 104, the sacrificial nanosheets 108 of the top nanosheet stacks 106 were laterally recessed and the inner spacers 138 were formed. As such, the inner spacers 138 physically separate the top source drain regions 142 from the sacrificial nanosheets 108 of the top nanosheet stacks 106. According to embodiments of the present invention, the top source drain regions 142 associated with the top nanosheet stacks 106 of a second-type, for example, N-type. For example, as previously described, N-type source drain regions can be formed by doping with arsenic (As) or phosphorous (P).

In stacked configurations, such as the structure 100 described herein, the bottom source drain regions 132 and the top source drain regions 142 can be of different types, formed from different materials, or doped with different dopants. In such cases, the bottom source drain regions 132 and the top source drain regions 142 would be of different types. For example, according to the disclosed embodiments the bottom source drain regions 132 are P-type and the top source drain regions 142 are N-type. In an alternative embodiment, the bottom source drain regions 132 are N-type and the top source drain regions 142 are P-type. In yet another embodiment, both the bottom source drain regions 132 and the top source drain regions 142 are either P-type or N-type.

Referring now to FIG. 9, the structure 100 is shown after forming a dielectric layer 144 according to an embodiment of the invention. FIG. 9 depicts a cross-sectional view taken along line X-X.

First, the dielectric layer 144 is formed by blanket depositing an interlayer dielectric material over the structure 100 according to known techniques. Specifically, the dielectric layer 144 is formed on the top source drain regions 142 and substantially fills the remaining space between the gate spacers 122.

The dielectric layer 144 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. In another embodiment, a self-planarizing material such as a spin-on glass (SOG) or a spin-on low-k dielectric material such as SiLK™ can be used as the dielectric layer 144. Using a self-planarizing dielectric material as the dielectric layer 144 can avoid the need to perform a subsequent planarizing step.

After the dielectric layer 144 is formed, the structure 100 is polished according to known techniques, such as, for example, chemical mechanical polishing techniques. Specifically, the dielectric layer 144, the gate spacers 122, and the masks 118 are polished until topmost surfaces of the dielectric layer 144 and the gate spacers 122 are flush, or substantially flush, with topmost surfaces of the sacrificial gates 120.

With continued reference to FIG. 9, the structure 100 is shown after selectively removing the sacrificial gates 120, the sacrificial nanosheets 108, and subsequently forming gate structures 146 according to an embodiment of the invention.

Next, the sacrificial gates 120 and the sacrificial nanosheets 108 are selectively removed according to known techniques. First, the sacrificial gates 120 are etched and removed selective to the gate spacers 122, the bottom nanosheet stacks 104, and the top nanosheet stacks 106 according to known techniques. Next, the sacrificial nanosheets 108 are etched and removed selective to the channel nanosheets 110 and the inner spacers 138 according to known techniques. Doing so is made possible by the different concentrations of germanium. In this case, the layers with germanium are removed selective to layers without germanium.

Next, the gate structures 146 are formed according to known techniques. First, a gate dielectric (not shown) is conformally deposited directly on exposed surfaces of the structure 100 within the gate cavities or openings and spaces left by removing the sacrificial gates 120 and the sacrificial nanosheets 108 according to known techniques. For example, the gate dielectric is conformally deposited on exposed surfaces of the channel nanosheets 110 and the inner spacers 138.

The gate dielectric is composed of any known gate dielectric materials, for example, oxide, nitride, and/or oxynitride. In an example, the gate dielectric can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the gate dielectric. In at least one embodiment, the gate dielectric is composed of hafnium oxide.

Next, a work function metal (not shown) is conformally deposited on the gate dielectric formed within the gate cavities according to known techniques. In at least one embodiment, the work function metal is made of the same conductive material across the entire structure. In at least another embodiment, the work function metal is made from different conductive materials in each of the devices illustrated the figures. In doing so, the different conductive materials would be deposited successively according to the design parameters and desired operation characteristics.

The work function metal can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium cabon (TiC), titanium aluminum (TiAl), titanium aluminum carbon (TiAlC), or multilayered combinations thereof. In some embodiments, the work function metal can include an NFET gate metal. In other embodiments, the work function metal can include a PFET gate metal. When multiple gate cavities are formed, as illustrated herein, embodiments of the present invention explicitly contemplate forming an NFET in at least one of the gate cavities and a PFET in at least another one of the gate cavities.

In some embodiments, gate metal or contact metal, is deposited directly on the work function metal, and fills the gate cavities. The first gate metal may include any suitable conductive material, such as, for example, copper, ruthenium, aluminum, tungsten, cobalt, or alloys thereof. After, excess conductive material can be polished using known techniques.

With continued reference to FIG. 9, the structure 100 is shown after forming top source drain contacts 148, bottom source drain contacts 150, back-end-of-line 152, and securing a carrier wafer 154 according to an embodiment of the invention.

First, additional interlayer dielectric material is deposited according to known techniques. The dielectric layer 144 illustrated in the figures includes the additional interlayer dielectric material.

Next, portions of the dielectric layer 144 are removed to expose the top source drain regions 142 and the bottom source drain regions 132, as well understood by persons having ordinary skill in the art. Next, the openings are filled with a conductive material to form the top source drain contacts 148 and the bottom source drain contacts 150, according to known techniques and as illustrated. Both the top source drain contacts 148 and the bottom source drain contacts 150 may include any suitable conductive material, such as, for example, copper, ruthenium, aluminum, tungsten, cobalt, or alloys thereof. In some embodiments, a metal silicide is formed at the bottom of the contact trenches prior to filling them with the conductive material. In some embodiments, neither the top source drain contacts 148 nor the bottom source drain contacts 150 do not contact the gate spacers 122, as illustrated. In other embodiments, some or all of the top source drain contacts 148 or the bottom source drain contacts 150 are self-aligned to, and direct contact, the gate spacers 122, and thus may be referred to as self-aligned contact structures. Additionally, in some embodiments the bottom source drain contacts 150 extend through, and direct contact the top source drain regions 142. In other embodiments the bottom source drain contacts 150 extend through, but are electrically and physically isolated from the top source drain regions 142 by a dielectric liner or barrier.

Finally, the back-end-of-line 152 (hereinafter BEOL 152) is formed and carrier wafer 154 is secured to a top of the structure 100 according to an embodiment of the invention. After forming the top source drain contacts 148 and the bottom source drain contacts 150, the BEOL 152 is subsequently formed according to known techniques. Next, the carrier wafer 154 is attached, or removably secured, to the BEOL 152. In general, and not depicted, the carrier wafer 154 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 154 according to known techniques.

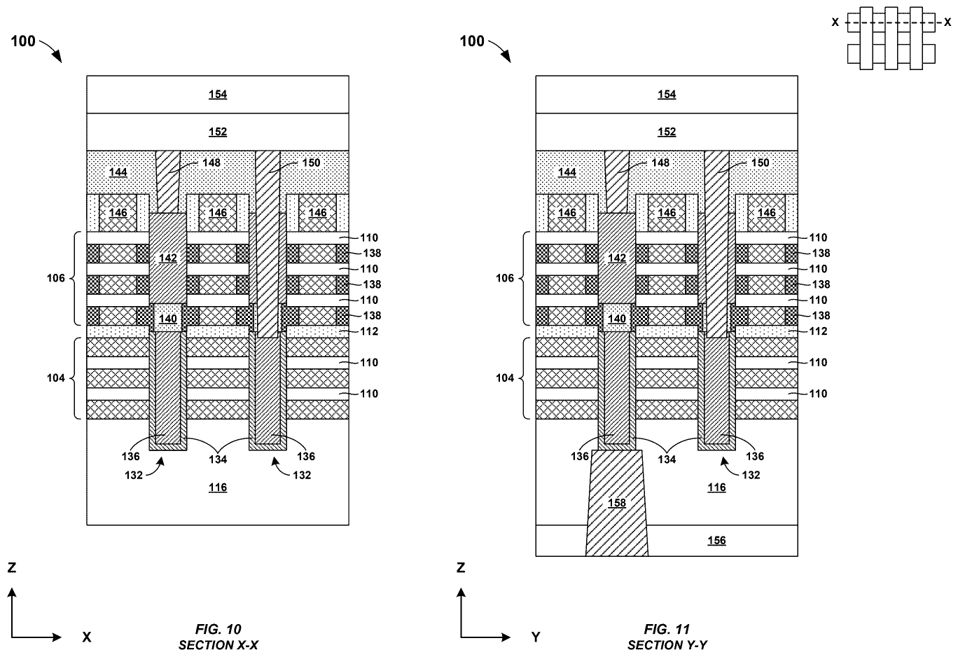

Referring now to FIG. 10, the structure 100 is shown after flipping the assembly and recessing the substrate 102 according to an embodiment of the invention. FIG. 10 depicts a cross-sectional view taken along line X-X.

First, the structure 100 is flipped 180 degrees to prepare for backside processing. In general, backside processing includes fabrication or processing of the structure 100 opposite the active device and wiring layers. Next, the substrate 102 is recessed according to known techniques. Specifically, the base substrate 114 and the etch stop layer 113 are recessed or completely removed to expose the top semiconductor layer 116, as shown. It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

Referring now to FIG. 11, the structure 100 is shown after forming a backside dielectric layer 156 and backside contact structures 158 according to an embodiment of the invention. FIG. 11 depicts a cross-sectional view taken along line X-X.

First, the backside dielectric layer 156 is deposited according to known techniques. Specifically, a backside dielectric material is blanket deposited across the backside of the structure 100. The backside dielectric layer 156 completely covers the top semiconductor layer 116, as illustrated. After deposition, known chemical mechanical polishing may be used to remove excess portions of the backside dielectric material from bottom surfaces of the structure 100. According to the disclosed embodiments, chemical mechanical polishing is used to planarize the surface of the backside dielectric layer 156.

Next, a mask (not shown) is deposited on the backside of the structure 100 and subsequently patterned to expose certain portions of the structure 100 according to known techniques. The mask can be an organic planarization layer (OPL) or a layer of material that is capable of being planarized or etched by known techniques. In an embodiment, for example, the mask can be an amorphous carbon layer able to withstand subsequent processing temperatures. The mask can preferably have a thickness sufficient to cover existing structures. After depositing the mask, a dry etching technique is applied to pattern or recess the mask according to known techniques. The mask is patterned consistent with a size and a location of subsequently formed backside contact structures. For example, after patterning the mask, portions of the structure 100 in contact regions are exposed.

Next, exposed portions of the backside dielectric layer 156 and underlying portions of the top semiconductor layer 116 are then selectively removed to form the backside contact trenches (not shown) according to known techniques. Specifically, the portions of the backside dielectric layer 156 and underlying portions of the top semiconductor layer 116 are removed using known etching techniques suitable to remove silicon selective to surrounding dielectrics.

In an embodiment, the portions of the backside dielectric layer 156 and underlying portions of the top semiconductor layer 116 are removed using an anisotropic etch such as, for example, reactive ion etching (RIE).

Specific to the disclosed embodiments, it is noted that the backside contact trenches extend into the top semiconductor layer 116 and expose bottoms of the bottom source drain regions 132. In some embodiments, portions of the first material 134 of the bottom source drain regions 132 are removed and bottoms of the second material 136 of the bottom source drain regions 132 are exposed.

Next, the backside contact trenches are filled with a conductive material to form the backside contact structures 158 according to known techniques. The backside contact structures 158 may include any suitable conductive material, such as, for example, copper, ruthenium, aluminum, tungsten, cobalt, or alloys thereof. In some embodiments, metal silicide regions (not shown) are formed on the exposed surfaces of the bottom source drain regions 132 prior to filling them with the conductive material, and according to known techniques. In doing so, metal silicide regions (not shown) may also form along sidewalls of the top semiconductor layer 116 exposed within the backside contact trenches. Silicide formation is otherwise believed to be conventional and not a subject of the disclose embodiments.

After deposition, excess conductive material can be polished using known techniques until bottommost surfaces of the backside contact structures 158 are flush, or substantially flush, with bottommost surfaces of the backside dielectric layer 156, as illustrated. After polishing, bottommost surfaces of the backside contact structures 158 are substantially flat. It is noted, the backside contact structures 158 may include, for example, backside source drain contacts, as illustrated, as well as backside gate contacts (not shown).

After forming the backside contact structures 158, backside wiring layers (not shown) are subsequently formed according to known techniques. The backside wiring layers typically include at least backside power rails and a backside power delivery network.

According to the embodiment illustrated in FIG. 11, the stacked transistor structures represented by the structure 100 have some distinctive notable features. For instance, the structure 100 includes a top transistor stacked above a bottom transistor where the bottom source drain regions 132 directly contact the gate structures 146, and the inner spacers 138 physically separate the top source drain regions 142 from the gate structures 146. Further, a width of each of the gate structures 146 measured at the top transistor is less than a width of each of the gate structures 146 measured at the bottom transistor. It is noted, the gate structures 146 are common to both top transistor and the bottom transistor. As previously indicated above, the bottom transistor is a P-type device having a bottom source drain region 132 having a first composition, and the top transistor is an N-type device having a top source drain region 142 having a second composition different from the first composition.

Additionally, because the channel nanosheets 110 and the sacrificial nanosheets 108 (which are important to transfer epitaxial strain along the nanosheet growth direction) are in direct contact the bottom source drain regions 132 until channel release (FIG. 9), the compressive strain on the channel nanosheets 110 is maintained. Such compressive strain is beneficial to mobility and decreases resistance of the P-type transistor.

Finally, because the gate structure 146 and the bottom source drain region 132 of the bottom transistor are relatively closer to each other as compared to the gate structure 146 and the top source drain region 142 of the top transistor, the overlap capacitance of the bottom transistor (P-type) will be higher than the overlap capacitance of the top transistor (N-type).

Referring now to FIG. 12, a structure 200 is shown during an intermediate step of a method of fabricating a transistor structure according to an alternative embodiment of the invention. Similar to the views presented and described above with respect to the structure 100, FIG. 12 depicts a cross-sectional view taken along line X-X.

The structure 200 is substantially similar to the structure 100 described above and is produced by a similar process flow described above with respect to the structure 100 except for the following differences. The structure 200 of FIG. 12 represents the resulting structure including backside contact liners 202.

Specifically, prior to forming the backside contact structures 158, the backside contact liners 202 are formed along sidewall portions of the backside contact trenches. The backside contact liners 202 are formed according to known techniques. Specifically, a dielectric material is conformally deposited across the backside of the structure and subsequently etched to remove substantially horizontal portions. In doing so, bottommost surfaces of the bottom source drain regions 132 become exposed, and the backside contact liners 202 remain along sidewalls of the backside contact trenches. The backside contact liners 202 are designed to electrically insulate the backside contact structures 158 from the top semiconductor layer 116 and may be integrated into the final structure as necessary.

According to the embodiment illustrated in FIG. 12, the stacked transistor structures represented by the structure 200 have similar distinctive notable features as those described above with respect to the structure 100.

Referring now to FIG. 13, a structure 300 is shown during an intermediate step of a method of fabricating a transistor structure according to an alternative embodiment of the invention. Similar to the views presented and described above with respect to the structure 100, FIG. 13 depicts a cross-sectional view taken along line X-X.

The structure 300 is substantially similar to the structure 100 described above and is produced by a similar process flow described above with respect to the structure 100 except for the following differences. The structure 300 of FIG. 13 represents the resulting structure including dielectric backside cuts 302.

Specifically, either before or after forming the backside contact structures 158, the dielectric backside cuts 302 are formed adjacent to the backside contact structures 158, according to known techniques and as illustrated. The dielectric backside cuts 302 are strategically positioned adjacent to the backside contact structures 158 to further reduce current leakage thought the top semiconductor layer 116.

According to the embodiment illustrated in FIG. 13, the stacked transistor structures represented by the structure 300 have similar distinctive notable features as those described above with respect to the structure 100.

Referring now to FIG. 14, a structure 400 is shown during an intermediate step of a method of fabricating a transistor structure according to an alternative embodiment of the invention. Similar to the views presented and described above with respect to the structure 100, FIG. 14 depicts a cross-sectional view taken along line X-X.

The structure 400 is substantially similar to the structure 100 described above and is produced by a similar process flow described above with respect to the structure 100 except for the following differences. The structure 400 of FIG. 14 represents the resulting structure where the channel nanosheets 110 of the bottom nanosheet stacks 104 are recessed prior to forming the bottom source drain regions 132, as discussed above with reference to FIG. 6.

Specifically, portions of the channel nanosheets 110 of the bottom nanosheet stacks 104 and portions of the top semiconductor layer 116 are removed according to known techniques and prior to forming the bottom source drain regions 132. For example, portions of the channel nanosheets 110 of the bottom nanosheet stacks 104 and portions of the top semiconductor layer 116 are removed using an isotropic etch process designed to etch silicon without attacking the silicon germanium of the sacrificial nanosheets 108. In doing so, the inner spacer liners 130 remain and protect surfaces of the top nanosheet stacks 106, see FIG. 6 for reference.

Next, the bottom source drain regions 132 are formed according to known techniques. As described above, the bottom source drain regions 132 associated with the bottom nanosheet stacks 104 are multilayered including the first material 134 and the second material 136. In the present example, the first material 134 of the structure 400 partially wraps end regions of the sacrificial nanosheets 108 of the bottom nanosheet stacks 104, as illustrated. In doing so, laterally recessing the channel nanosheets 110, as described immediately above, produces a larger overall surface area from which the source drain regions 132 are grown. Additionally, the additional thickness of the first material 134 of the structure 400 helps further preserve the desired stress of the bottom transistors formed from the bottom nanosheet stacks 104. Moreover, the structure 400 provides increased contact area between the channel nanosheets 110 and the bottom source drain regions 132.

According to the embodiment illustrated in FIG. 14, the stacked transistor structures represented by the structure 400 have similar distinctive notable features as those described above with respect to the structure 100.

With continued reference to FIG. 11, and according to an embodiment, the structure 100 includes a bottom transistor including a bottom source drain region, where the bottom source drain region directly contacts a gate structure, and a top transistor including a top source drain region, where the top source drain region is physically separated from the gate structure.

With continued reference to FIG. 11, and according to an embodiment, the bottom transistor is a P-type device and the top transistor is an N-type device.

With continued reference to FIG. 11, and according to an embodiment, the bottom source drain region includes a first composition and the top source drain region includes a second composition different from the first composition.

With continued reference to FIG. 11, and according to an embodiment, the bottom source drain region comprises a first material and a second material which is different from the first material.

With continued reference to FIG. 11, and according to an embodiment, a bottommost surface of the bottom source drain region is lower than a bottommost surface of the gate structure.

With continued reference to FIG. 11, and according to an embodiment, the structure further includes a substrate immediately below the bottom transistor, where the bottom source drain region directly contacts the substrate.

With continued reference to FIG. 11, and according to an embodiment, the structure further includes a backside source drain contact immediately below and directly contacting the bottom source drain region.

With continued reference to FIG. 11, and according to an embodiment, the structure 100 includes a bottom transistor including a bottom source drain region, where the bottom source drain region directly contacts a gate structure, and a top transistor including a top source drain region and inner spacers, where the inner spacers physically separate the top source drain region from the gate structure.

With continued reference to FIG. 11, and according to an embodiment, the structure 100 includes a bottom transistor including a bottom source drain region, where the bottom source drain region directly contacts a gate structure, and a top transistor including a top source drain region, where the top source drain region is physically separated from the gate structure, where a width of the gate structure measured at the top transistor is less than a width of the gate structure measured at the bottom transistor.

Various examples may possibly be described by one or more of the following features in the following numbered clauses:

Clause 1: A stacked transistor structure including: a bottom transistor including a bottom source drain region, where the bottom source drain region directly contacts a gate structure, and a top transistor including a top source drain region, where the top source drain region is physically separated from the gate structure.

Clause 2: The semiconductor structure according to clause 1, where the bottom transistor is a P-type device and the top transistor is an N-type device.

Clause 3: The semiconductor structure according to clauses 1 and 2, where the bottom source drain region includes a first composition and the top source drain region includes a second composition different from the first composition.

Clause 4: The semiconductor structure according to clauses 1, 2, and 3, where the bottom source drain region includes a first material and a second material which is different from the first material.

Clause 5: The semiconductor structure according to clauses 1, 2, 3, and 4, where a bottommost surface of the bottom source drain region is lower than a bottommost surface of the gate structure.

Clause 6: The semiconductor structure according to clauses 1, 2, 3, 4, and 5, further include a substrate immediately below the bottom transistor, where the bottom source drain region directly contacts the substrate.

Clause 7: The semiconductor structure according to clauses 1, 2, 3, 4, 5, and 6, further include a backside source drain contact immediately below and directly contacting the bottom source drain region.

Clause 8: A stacked transistor structure including: a bottom transistor including a bottom source drain region, where the bottom source drain region directly contacts a gate structure, and a top transistor including a top source drain region and inner spacers, where the inner spacers physically separate the top source drain region from the gate structure.

Clause 9: The semiconductor structure according to clause 8, where the bottom transistor is a P-type device and the top transistor is an N-type device.

Clause 10: The semiconductor structure according to clauses 8 and 9, where the bottom source drain region includes a first composition and the top source drain region includes a second composition different from the first composition.

Clause 11: The semiconductor structure according to clauses 8, 9, and 10, where the bottom source drain region includes a first material and a second material which is different from the first material.

Clause 12: The semiconductor structure according to clauses 8, 9, 10, and 11, where a bottommost surface of the bottom source drain region is lower than a bottommost surface of the gate structure.

Clause 13: The semiconductor structure according to clauses 8, 9, 10, 11, and 12, further includes a substrate immediately below the bottom transistor, where the bottom source drain region directly contacts the substrate.

Clause 14: The semiconductor structure according to clauses 8, 9, 10, 11, 12, and 13, further includes a backside source drain contact immediately below and directly contacting the bottom source drain region.

Clause 15: A stacked transistor structure including: a bottom transistor including a bottom source drain region, where the bottom source drain region directly contacts a gate structure, and a top transistor including a top source drain region, where the top source drain region is physically separated from the gate structure, where a width of the gate structure measured at the top transistor is less than a width of the gate structure measured at the bottom transistor.

Clause 16: The semiconductor structure according to clause 15, where the bottom transistor is a P-type device and the top transistor is an N-type device.

Clause 17: The semiconductor structure according to clauses 15 and 16, where the bottom source drain region includes a first composition and the top source drain region includes a second composition different from the first composition.

Clause 18: The semiconductor structure according to clauses 15, 16, and 17, where the bottom source drain region includes a first material and a second material which is different from the first material.

Clause 19: The semiconductor structure according to clauses 15, 16, 17, and 18, where a bottommost surface of the bottom source drain region is lower than a bottommost surface of the gate structure.

Clause 20: The semiconductor structure according to clauses 15, 16, 17, 18, and 19, further includes a substrate immediately below the bottom transistor, where the bottom source drain region directly contacts the substrate.

Clause 21: The semiconductor structure according to clauses 15, 16, 17, 18, 19 and 20, further includes a backside source drain contact immediately below and directly contacting the bottom source drain region.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A stacked transistor structure comprising:
a bottom transistor comprising a bottom source drain region, wherein the bottom source drain region directly contacts a gate structure; and
a top transistor comprising a top source drain region, wherein the top source drain region is physically separated from the gate structure.

2. The stacked transistor structure according to claim 1, wherein the bottom transistor is a P-type device and the top transistor is an N-type device.

3. The stacked transistor structure according to claim 1, wherein the bottom source drain region comprises a first composition and the top source drain region comprises a second composition different from the first composition.

4. The stacked transistor structure according to claim 1, wherein the bottom source drain region comprises a first material and a second material which is different from the first material.

5. The stacked transistor structure according to claim 1, wherein a bottommost surface of the bottom source drain region is lower than a bottommost surface of the gate structure.

6. The stacked transistor structure according to claim 1, further comprising:
a substrate immediately below the bottom transistor, wherein the bottom source drain region directly contacts the substrate.

7. The stacked transistor structure according to claim 1, further comprising:
a backside source drain contact immediately below and directly contacting the bottom source drain region.

8. A stacked transistor structure comprising:
a bottom transistor comprising a bottom source drain region, wherein the bottom source drain region directly contacts a gate structure; and
a top transistor comprising a top source drain region and inner spacers, wherein the inner spacers physically separate the top source drain region from the gate structure.

9. The stacked transistor structure according to claim 8, wherein the bottom transistor is a P-type device and the top transistor is an N-type device.

10. The stacked transistor structure according to claim 8, wherein the bottom source drain region comprises a first composition and the top source drain region comprises a second composition different from the first composition.

11. The stacked transistor structure according to claim 8, wherein the bottom source drain region comprises a first material and a second material which is different from the first material.

12. The stacked transistor structure according to claim 8, wherein a bottommost surface of the bottom source drain region is lower than a bottommost surface of the gate structure.

13. The stacked transistor structure according to claim 8, further comprising:
a substrate immediately below the bottom transistor, wherein the bottom source drain region directly contacts the substrate.

14. The stacked transistor structure according to claim 8, further comprising:
a backside source drain contact immediately below and directly contacting the bottom source drain region.

15. A stacked transistor structure comprising:
a bottom transistor comprising a bottom source drain region, wherein the bottom source drain region directly contacts a gate structure; and
a top transistor comprising a top source drain region, wherein the top source drain region is physically separated from the gate structure,
wherein a width of the gate structure measured at the top transistor is less than a width of the gate structure measured at the bottom transistor.

16. The stacked transistor structure according to claim 15, wherein the bottom transistor is a P-type device and the top transistor is an N-type device.

17. The stacked transistor structure according to claim 15, wherein the bottom source drain region comprises a first composition and the top source drain region comprises a second composition different from the first composition.

18. The stacked transistor structure according to claim 15, wherein the bottom source drain region comprises a first material and a second material which is different from the first material.

19. The stacked transistor structure according to claim 15, wherein a bottommost surface of the bottom source drain region is lower than a bottommost surface of the gate structure.

20. The stacked transistor structure according to claim 15, further comprising:
a substrate immediately below the bottom transistor, wherein the bottom source drain region directly contacts the substrate.
